(19) United States
(12) Patent Application Publication
(10) Pub. No.: US 2025/0014650 A1
(43) Pub. Date: Jan. 9, 2025

(54) MEMORY ERASE METHOD FOR MEMORY DEVICE AND MEMORY DEVICE THEREFORE

(71) Applicant: MACRONIX International Co., Ltd., Hsinchu (TW)

(72) Inventors: You-Liang Chou, Taichung City (TW); Wen-Jer Tsai, Hualien County (TW); Chih-Chieh Cheng, Hsinchu County (TW)

(73) Assignee: MACRONIX International Co., Ltd., Hsinchu (TW)

(21) Appl. No.: 18/474,228

(22) Filed: Sep. 26, 2023

Related U.S. Application Data
(60) Provisional application No. 63/524,854, filed on Jul. 3, 2023.

(51) Int. Cl. G11C 16/16; G11C 16/04; G11C 16/10; G11C 16/34

(52) U.S. Cl. CPC G11C 16/16; G11C 16/0433; G11C 16/102; G11C 16/3495

(57) ABSTRACT

A memory erase method for a memory device and a memory device therefore are provided. The memory device is a 3D NAND flash with high capacity and high performance. The memory erase method includes following steps: providing a memory block, wherein the memory block comprises memory cell strings, the memory cell strings include memory cells, string selection transistors and ground selection transistors; respectively applying corresponding erase voltages to corresponding word lines, a common source line, a corresponding bit line, the string selection transistor and the ground selection transistor of each of the memory cell strings. The voltage difference between a bit line erase voltage and a string selection line erase voltage or the voltage difference between the common source line erase voltage and the ground selection line erase voltage is less than or equal to a predetermined voltage difference, and the memory cells of the memory cell strings randomly classified as a type-1 erase bit or a type-2 erase bit.

### CROSS-REFERENCE TO RELATED APPLICATION

This application claims the priority benefit of U.S. provisional application Ser. No. 63/524,854 filed on Jul. 3, 2023. The entirety of the above-mentioned patent application is hereby incorporated by reference herein and made a part of this specification.

### BACKGROUND

### Technical Field

The disclosure relates to a memory erase technology applied to a memory device (e.g., NAND flash memory), and in particular relates to a memory erase method for a memory device and a memory device therefore.

### Description of Related Art

Integrated circuit memory with high capacity and high performance, which includes 3D NAND flash memory, is continuously developing. It aims to increase data storage density by reducing the size of memory cells using 3D stacking technology and multi-level cells (MLC). On the other hand, physically unclonable function (PUF) technology is based on process variability and material characteristics, which result in objects manufactured through semiconductor processes generating highly random and unpredictable data. The data may be used for identity verification, device keys, communication security, and other purposes, and are unique.

The PUF technology in 3D flash memory may be implemented based on program disturbance, read disturbance or program operation latency, but these approaches may be limited by the program erase cycle (P/E cycle) in the flash memory. In other words, the flash memory after a large amount of programming/erasing may change the physical characteristics of the memory cells, thus making the PUF data unstable.

### SUMMARY

A memory erase method for a memory device and the memory device therefore are provided, in which an erasing operation is performed on a memory block so that the memory cells in the memory cell strings randomly generate different threshold voltage distributions, so as to obtain the PUF data.

The memory erase method of the memory device of the embodiment of the disclosure includes the following operation. A memory block is provided, in which the memory block comprises a plurality of memory cell strings including a plurality of memory cells, a plurality of string selection transistors, and a plurality of ground selection transistors. Each of the plurality of memory cell strings includes a string selection transistor, multiple memory cells among the plurality of memory cells and a ground selection transistor are connected in series. Each memory cell string coupled to a corresponding bit line through a corresponding string selection transistor, and coupled to a common source line through a corresponding ground selection transistor. The multiple of memory cells connected to a plurality of corresponding word lines. A word line erase voltage is applied to the plurality of corresponding word lines of each of the plurality of memory cell strings. A common source line erase voltage is applied to the common source line. A bit line erase voltage is applied to a corresponding bit line of each of the plurality of memory cell strings. A string selection line erase voltage is applied to the string selection transistor of each of the plurality of memory cell strings. And, a ground selection line erase voltage is applied to the ground selection transistor of each of the plurality of memory cell strings. A voltage difference between the bit line erase voltage and the string selection line erase voltage or a voltage difference between the common source line erase voltage and the ground selection line erase voltage is less than or equal to a predetermined voltage difference. The plurality of memory cells of the plurality of memory cell strings randomly classified as a type-1 erase bit or a type-2 erase bit.

A memory device according to an embodiment of the disclosure includes a memory block and a memory controller. The memory block comprises a plurality of memory cell strings. The plurality of memory cell strings including a plurality of memory cells, a plurality of string selection transistors and a plurality of ground selection transistors. Each of the plurality of memory cell strings includes a string selection transistor, multiple memory cells among the plurality of memory cells and a ground selection transistor are connected in series. Each memory cell string coupled to a corresponding bit line through a corresponding string selection transistor, and coupled to a common source line through a corresponding ground selection transistor. The multiple of memory cells connected to a plurality of corresponding word lines. The memory controller is coupled to the memory block and the memory controller controls a plurality of voltage drivers to perform: applying a word line erase voltage to the plurality of corresponding word lines of each of the plurality of memory cell strings, applying a common source line erase voltage to the common source line, applying a bit line erase voltage to a corresponding bit line of each of the plurality of memory cell strings, applying a string selection line erase voltage to the string selection transistor of each of the plurality of memory cell strings, and applying a ground selection line erase voltage to the ground selection transistor of each of the plurality of memory cell strings, wherein a voltage difference between the bit line erase voltage and the string selection line erase voltage or a voltage difference between the common source line erase voltage and the ground selection line erase voltage is less than or equal to a predetermined voltage difference, the plurality of memory cells of the plurality of memory cell strings randomly classified as a type-1 erase bit or a type-2 erase bit.

Based on the above, the memory erase method for the memory device and the memory device and therefore described in the embodiment of the disclosure utilize erase voltages which are close to threshold values of a gate induced drain leakage (GIDL) erasing operation and applies these erase voltages to the plurality of memory cells in the plurality of memory cell strings to perform the GIDL erasing operation on the memory blocks, so that the multiple of memory cells in the plurality of memory cell strings randomly generate different threshold voltage distributions, so as to obtain the PUF data. Therefore, in the embodiment of the disclosure, the memory erasing operation is performed on the memory block so that the plurality of memory cells in the plurality of memory cell strings randomly generate different threshold voltage distributions, and then correspondingly generate PUF data according to the erased memory cell strings. Moreover, the threshold voltage distribution of each memory cells in the erased memory cell string is the same, that is, the corresponding PUF data generated by each page in the memory device is the same. Therefore, when the programming-erasing count of a specific page in the memory device exceeds the wear threshold, another page of the memory device may be used to replace the specific page for increasing the stability of the PUF data.

### BRIEF DESCRIPTION OF THE DRAWINGS

FIG. 1 is a structural schematic diagram of a memory block 150 in a three-dimensional memory chip according to an embodiment of the disclosure.

FIG. 2 is a schematic diagram of a gate induced drain leakage (GIDL) erasing method according to an embodiment of the disclosure.

FIG. 3 is a schematic diagram of the influence of generated holes owing to gate induced drain leakage (GIDL) on the threshold voltage distribution in a memory cell according to an embodiment of the disclosure.

FIG. 4 is a schematic diagram of threshold voltage distribution and physically unclonable function (PUF) data in a memory cell according to an embodiment of the disclosure.

FIG. 5 is a flowchart of a memory erase method of a memory device according to an embodiment of the disclosure, which is also a flowchart of a data generating method of a physically unclonable function (PUF) in an embodiment of the disclosure.

FIG. 6 is a schematic diagram of a portion of the memory cell string and pages in a memory cell block according to an embodiment of the disclosure.

### DETAILED DESCRIPTION OF DISCLOSED EMBODIMENTS

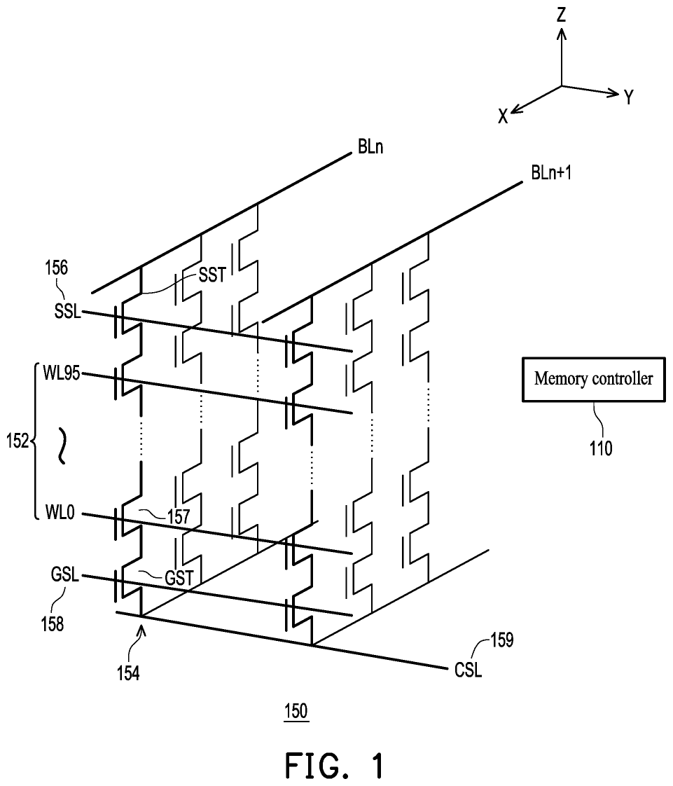

FIG. 1 is a structural schematic diagram of a memory block 150 in a three-dimensional memory chip according to an embodiment of the disclosure. Multiple memory cells in the memory block 150 are configured in three dimensions, for example, an XYZ coordinate system. Taking the memory cell 157 as an example, the memory cell 157 is coupled to the corresponding word line WL0 and bit line BLn. The word lines (e.g., word lines WL0 to WL95) formed by the conductive layers or the word line layers and the memory cells coupled thereto form multiple pages 152. In other words, the memory cells in the memory block (i.e., block) 150 are divided into multiple pages 152. Each page may be a layer of memory cells in the XY plane. The memory cells on the same layer (the same page) may be coupled to a same word line (e.g., word lines WL0 or WL5) and obtain a same corresponding word line voltage. The memory cells on the different layers (different pages) may be coupled to different word lines (e.g., word line WL0 and WL95) and obtain different corresponding word line voltages. In other words, one page in the memory block 150 is constructed by the memory cells which are connected with one of the word lines (for instance, one of word lines WL0-WL95) on the memory cell strings. Each of the pages 152 may be connected to corresponding contacts in a driver circuit through one of the word lines WL0-WL95 coupling with this page, for example to an X decoder (or knowns as a scan driver). Each line has a corresponding voltage driver, and these voltage drivers may be controlled by the memory controller 110 or corresponding hardware. Memory cells in the memory cell string 154 belong to different pages.

Each memory cell string (e.g., the string 154) includes multiple memory cells connected in series vertically along the Z direction. The memory cell strings includes a plurality of memory cells (e.g., the memory cell 157), a plurality of string selection transistors SST coupled to a string selection line (SSL) 156 and a plurality of ground selection transistors GST coupled to a ground selection line (GSL) 158. The string 154 is connected to one or more drivers, such as data drivers. The memory cell 157 is connected to a common source line (CSL) 159 via a ground select transistor GST. The SSL 156 may be a conductive line or conductive layer formed on top of each page 152 (or word line layer). The memory block 150 may include multiple SSLs 156 provided on a top page of the pages 152. The GSL 158 may be a conductive line or conductive layer formed on the bottom of each page 152 (or word line layer). The CSL 159 may be a conductive layer or multiple conductive lines formed under the ground selection line (GSL) 158 and over the substrate of the three-dimensional memory chip. Several dummy lines or corresponding layers (not shown) may also be provided between the string selection line SSL 156 and the topmost page 152, or between the ground selection line GSL 158 and the bottommost page 152.

The embodiment of the disclosure is based on the process variability and the variability of gate induced drain leakage (GIDL) erasing ability. By adjusting the erase voltages of GIDL erasing method so that the threshold voltage distribution is unstable in the memory block, the memory cells may be classified into fast erase memory cells and slow erase memory cells. Accordingly, different bits (e.g., a type-1 erase bit or a type-2 erase bit) in the physically unclonable function (PUF) data may be generated. Moreover, the aforementioned GIDL erasing method causes all memory cells in each memory cell string to have the same threshold voltage distribution, so the PUF data generated by each page is the same. While programming-erasing count of a specific page exceeds a wear threshold, another page are used as the specific page for generated the same PUF data in an embodiment of the disclosure, thereby reducing the influence of the program erase cycle on the PUF data. Various embodiments are given below for detailed illustration.

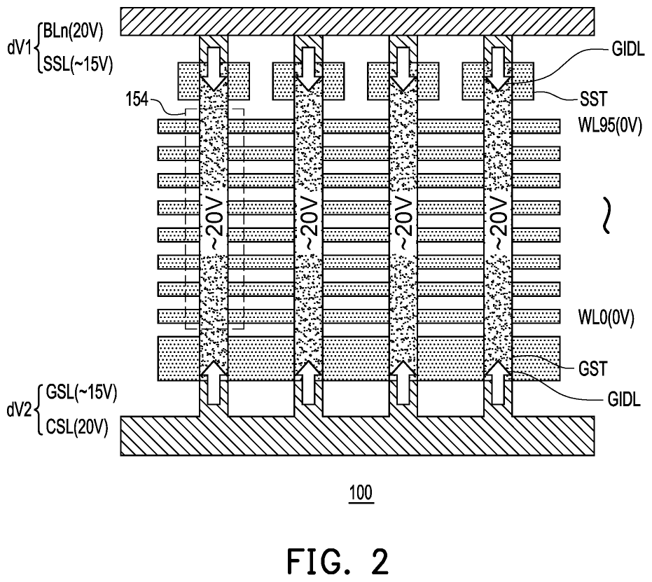

FIG. 2 is a schematic diagram of a gate induced drain leakage (GIDL) erasing method according to an embodiment of the disclosure. FIG. 2 shows some components of FIG. 1 to illustrate the GIDL erasing method. As shown in FIG. 2, the memory block 150 may use the GIDL erasing method to set all memory cells to logic “1”. The GIDL erasing method is an erasing method performed on memory cells by using the string selection transistor SST and/or the ground selection transistor GST formed by doping technology to adjust the threshold voltage of each memory cell through corresponding hole flow generated by the voltage difference between the bit line BL and the string selection line SSL (e.g., the voltage difference dV1 in FIG. 2) and/or the voltage difference between the ground selection line GSL and the common source line CSL (e.g., the voltage difference dV2 in FIG. 2).

The GIDL erasing method is implemented through the string selection transistor SST and/or the ground selection transistor GST formed by doping technology. The doping condition of the string selection transistor SST and/or the ground selection transistor GST is slightly different due to the influence of semiconductor process variability, thereby the aforementioned voltage difference dV1 or dV2 affects the threshold voltage distribution in the memory cell.

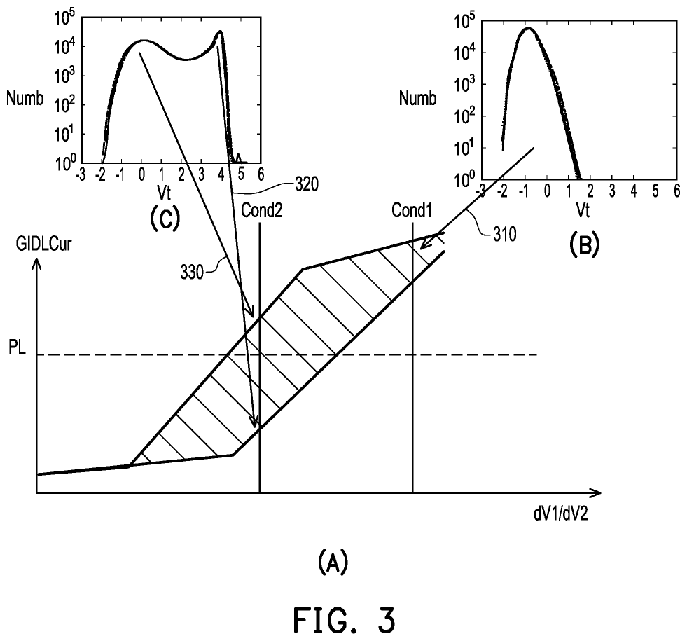

FIG. 3 is a schematic diagram of the influence of generated holes owing to gate induced drain leakage (GIDL) on the threshold voltage distribution in a memory cell according to an embodiment of the disclosure. The GIDLCur marked on the Y-axis in the graph (A) of FIG. 3 indicates the current value of the specific memory cell string subjected to the GIDL erasing method, and the value PL on the Y-axis indicates a standard that is sufficient as the GIDL erasing method. A current value of the GIDL erasing method lower than the value PL indicates that the memory cell has failed in performing the GIDL erasing method; a current of the GIDL erasing method higher than the value PL indicates that the memory cell is successful in performing the GIDL erasing method. The dV1/dV2 marked on the X-axis in the central graph of FIG. 3 indicates the voltage difference dV1 between the bit line BL and the string selection line SSL or the voltage difference dV2 between the ground selection line GSL and the common source line CSL. Graph (B) and graph (C) in FIG. 3 respectively show the memory cell number Numb and the corresponding threshold voltage Vt distribution when the voltage difference dV1/dV2 is under condition Cond1 or condition Cond2. The condition Cond1 may also be referred to as a strong erasing condition, which has a larger voltage difference dV1/dV2; the condition Cond2 may also be referred to as a weak erasing condition, which has a smaller voltage difference dV1/dV2. Moreover, in this embodiment, the voltage difference dV1/dV2 of the condition Cond2 as shown in graph (C) of FIG. 3 is approximately less than 5V, so it is also referred to as the GIDL erasing method with a lack of enough current.

It may be known from FIG. 3 that in the normal GIDL erasing method, a larger voltage difference dV1/dV2 is provided (e.g., the condition Cond1), so that the memory cell number Numb and the corresponding threshold voltage Vt distribution in the memory cell are distributed on a specific convex curve, as shown in the graph (B) of FIG. 3, so that each erased memory cell has a similar threshold voltage, as shown by arrow 310. On the other hand, in the embodiment of the disclosure, a smaller voltage difference dV1/dV2 is provided (e.g., the condition Cond2), so that the memory cell number Numb and the corresponding threshold voltage Vt distribution in the memory cell have two peaks, as shown in the graph (C) of FIG. 3. The first peak of the graph (C) in FIG. 3 indicates the memory cell corresponding to the current value of the GIDL erasing method higher than the value PL (referred to as a strong erasing memory cell), as shown by the arrow 320. The second peak of the graph (C) in FIG. 3 indicates the memory cell corresponding to the current value of the GIDL erasing method lower than the value PL (referred to as a weak erasing memory cell), as shown by the arrow 330.

In other words, in this embodiment of the disclosure, the GIDL erasing method is utilized with the voltage difference dV1 between the bit line BL and the string selection line SSL or the voltage difference dV2 between the ground selection line GSL and the common source line CSL to provide corresponding voltage difference value according to the condition Cond2 in the graph (C) of FIG. 3, so that the memory cell presents the threshold voltage distribution in the graph (C) of FIG. 3. The memory cells are randomly classified into strong erasing memory cells and weak erasing memory cells according to the threshold voltage distribution of the memory cells. The strong erasing memory cells are set as the type-1 erase bit (e.g., bit logic “1”), the weak erasing memory cells are set as the type-2 erase bit (e.g., bit logic “0”), and thereby the PUF data generated by the influence of process variability is obtained. All memory cells in each memory cell string present the same type of memory cell. For example, as long as one memory cell in the specific memory cell string is measured as a strong erasing memory cell, the other memory cells in this specific memory cell string are also strong erasing memory cells. As long as one memory cell in the specific memory cell string is measured as a weak erasing memory cell, the other memory cells in this specific memory cell string are also weak erasing memory cells.

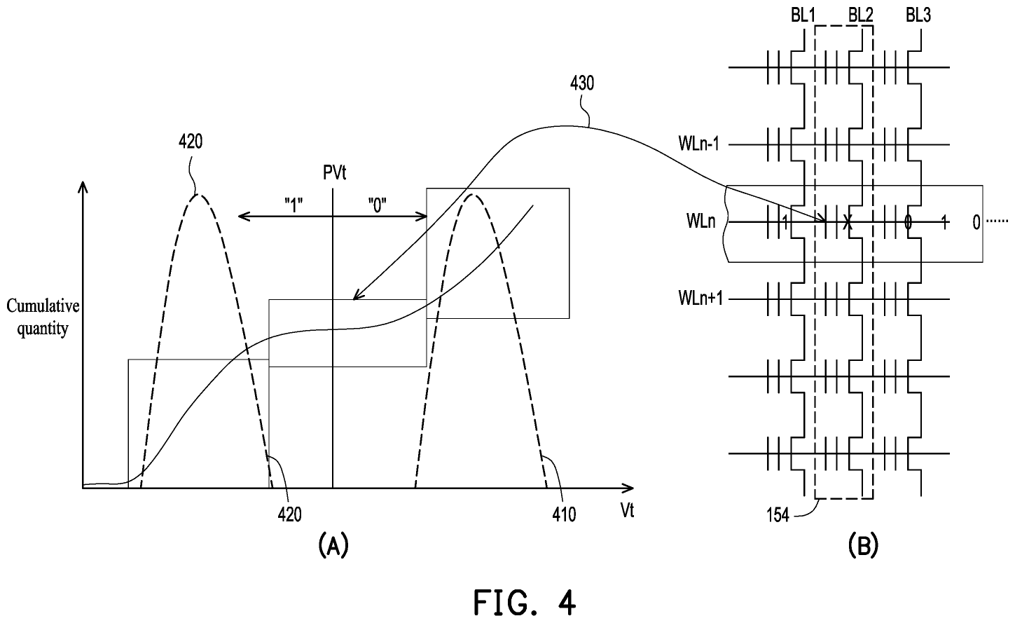

FIG. 4 is a schematic diagram of threshold voltage distribution and PUF data in a memory cell according to an embodiment of the disclosure. The Y-axis of the graph (A) in FIG. 4 represents the cumulative quantity of memory cells, the X-axis represents the threshold voltage of the memory cells, the convex dashed line 410 represents the threshold voltage distribution of the weak erasing memory cells, and the convex dashed line 420 represents the threshold voltage distribution of the strong erasing memory cells. The arrow 430 and the corresponding box mark the range of memory cells with unstable values. The right portion (B) of FIG. 4 shows a portion of the memory block. Taking the page corresponding to the portion of word line WLn in (B) as an example, other memory cell strings may use the predetermined threshold voltage value PVt in FIG. 4 to distinguish the corresponding memory cell as a strong erasing memory cell (corresponding to logic “1”) or a weak erasing memory cell (corresponding to logic “0”). If the threshold voltage in the memory cell of the memory cell string 154-1 is located at the box marked by the arrow 430, it indicates that the threshold voltage value corresponding to the memory cells are in an unstable memory cell range, and the embodiment of the disclosure filters out such memory cells and ignores them, and does not use the memory cells of the memory cell string 154-1 to generate PUF data.

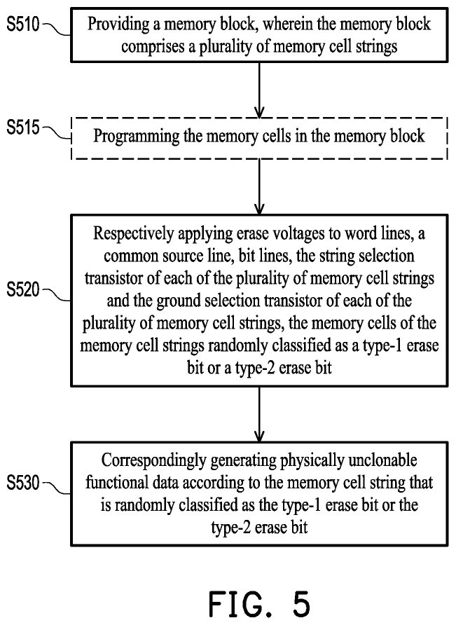

FIG. 5 is a flowchart of a memory erase method of a memory device according to an embodiment of the disclosure, which is also a flowchart of a data generating method of a physically unclonable function (PUF) in an embodiment of the disclosure. The method in FIG. is applicable to the memory block structures in FIG. 1 and FIG. 2, and may be implemented by a memory controller or corresponding hardware.

In step S510, a memory block (e.g., the memory block 150 in FIG. 1) is provided. The memory block 150 includes a plurality of memory cell strings (e.g., the memory cell string 154). The memory cell strings include a plurality of memory cells (e.g., the memory cell 157), a plurality of string selection transistors (e.g., the string selection transistor SST) and a plurality of ground selection transistors (e.g., the ground selection transistor GST). One or more the string selection transistors among the plurality of string selection transistors (e.g., the string selection transistor SST), multiple memory cells among the plurality of memory cells (e.g., the memory cell 157) and one or more the ground selection transistors among the plurality of ground selection transistors (e.g., the ground selection transistor GST) are connected in series to construct each memory cell string (e.g., the memory cell string 154). The memory cell string 154 is coupled to the corresponding bit line BLn through the corresponding string selection transistor SST, and the memory cell string 154 is coupled to the common source line CSL through the corresponding ground selection transistor. Each memory cell is connected to multiple corresponding word lines (e.g., word lines WL0 to WL95).

In step S515, before performing step S520 in FIG. 5, the memory controller may program the plurality of memory cells in the memory block. This embodiment adopts page programming. In step S520, the memory controller applies corresponding erase voltages to the word lines, common source lines, bit lines, string selection transistors, and ground selection transistors in the memory block 150. In detail, in this embodiment, the word line erase voltage (e.g., 0V) is applied to the corresponding word lines WL0 to WL95 of each of the plurality of memory cell strings. The common source line erase voltage (e.g., 20V) is applied to the common source line CSL. The bit line erase voltage (e.g., 20V) is applied to the corresponding bit line BLn (e.g., BL1, BL2, BL3, etc.) to each of the plurality of memory cell strings (e.g., the memory cell string 154). The string selection line erase voltage is applied to the string selection transistor SST of each of the memory cell strings. The ground selection line erase voltage is applied to the ground selection transistor GST of each of the memory cell strings. The voltage difference dV1 between the bit line erase voltage and the string selection line erase voltage is required to be less than or equal to the predetermined voltage difference (5V), in other words, the voltage difference dV1 between the bit line erase voltage and the string selection line erase voltage is between 0V and 5V. Similarly, the voltage difference dV2 between the common source line erase voltage and the ground selection line erase voltage is required to be less than or equal to a predetermined voltage difference (5V). The voltage difference dV1 and the voltage difference dV2 in this embodiment may be different from each other. Based on the foregoing, the string selection line erase voltage (i.e., the voltage on the string selection line SSL) and the ground selection line erase voltage (i.e., the voltage on the ground selection line GSL) are selectively approximately 15V in this embodiment.

After steps S510 and S520, the GIDL erasing operation is performed on the plurality of memory cells of the plurality of memory cell strings (e.g., the memory cell string 154), and all the multiple of memory cells in the memory cell string 154 are randomly classified into a type-1 erase bit or a type-2 erase bit. Moreover, after the GIDL erasing operation, all of the multiple memory cells in the specific memory cell string are the above-mentioned type-1 erase bit, or all of the multiple memory cells in the specific memory cell string are the above-mentioned type-2 erase bit. In other words, the erase bit type of each of the multiple of memory cell in the memory cell string is the same, and each memory cell string may only generate one bit in the PUF data.

In step S530, the memory controller correspondingly generates PUF data according to the memory cell string randomly classified as the type-1 erase bit or the type-2 erase bit. The memory controller classifies the memory cells into the type-1 erase bit or the type-2 erase bit according to the threshold voltage of the memory cell. Moreover, in the condition where the memory cell cannot be classified as the aforementioned type-1 erase bit or the aforementioned type-2 erase bit by using the threshold voltage of the memory cell, that is, the threshold voltage of the aforementioned memory cell is located in the unstable memory cell range as shown by the arrow 430 and the corresponding box in FIG. 4, then the unclassifiable memory cells are not used to generate PUF data.

In the aforementioned step S515 of this embodiment, the memory block 150 in FIG. 1 may be programmed on a per-page basis (i.e., page programming), and erased on the basis of the entire memory block 150 (i.e., block erasing). However, since the present embodiment adopts GIDL erasing, the multiple of memory cells in a memory cell string display the same type of eras bit, and each memory cell string may only generate one bit of PUF data. Moreover, if the entire memory block is used for erasing, each memory cell in the memory block increases the cumulative quantity of program erase cycle (P/E cycle) in the flash memory by one. Therefore, another example in the embodiment of the disclosure describes the way of not using block erasing but using page erasing instead.

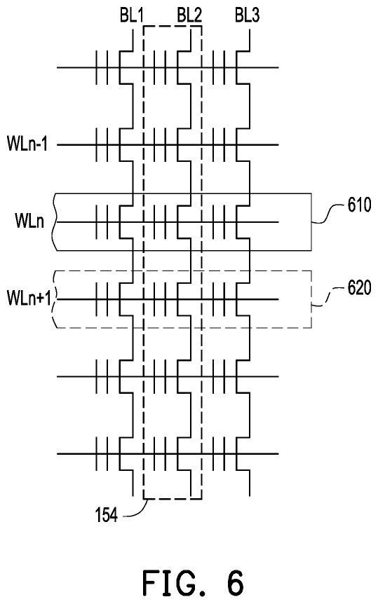

FIG. 6 is a schematic diagram of a portion of the memory cell string and pages in a memory cell block according to an embodiment of the disclosure. As shown in FIG. 6, the embodiment of the disclosure adopts page programming and page erasing. In other words, the memory erase method of the present embodiment or the data generating method of the PUF programs all of the memory cells in a specific page (e.g., page 610) of the pages before the cells are randomly classified as a type-1 erase bit or a type-2 erase bit.

Then, the memory controller determines whether the programming-erasing count of the specific page 610 exceeds the wear threshold. If the programming-erasing count does not exceed the wear threshold, it indicates that the PUF data generated by using the specific page 610 has less probability of being unstable due to the limitation of the program erase cycle in the flash memory. Therefore, in this embodiment, the specific page 610 is used to continue the step S520 and step S530 in FIG. 5 to generate PUF data. In contrast, if the programming-erasing count exceeds the wear threshold, it indicates that the PUF data generated by the specific page 610 has a high probability of being unstable due to the limitation of the program erase cycle in the flash memory. At this time, the memory controller of this embodiment takes another page (e.g., the page 620 corresponding to the word line WLn+1) as the aforementioned specific page, and proceeds to step S520 and step S530 in FIG. 5 to generate PUF data. The reason why a replacement page may be used to generate PUF data is that all the multiple of memory cells in each memory cell string undergo GIDL erasing operation and are classified as the same type of erase bit. That is, in this embodiment, the corresponding PUF data generated by each page through step S510 to step S530 in FIG. 5 is the same.

To sum up, the memory erase method for the memory device and the memory device and therefore described in the embodiment of the disclosure utilize erase voltages which are close to threshold values of a gate induced drain leakage (GIDL) erasing operation and applies these erase voltages to the plurality of memory cells in the plurality of memory cell strings to perform the GIDL erasing operation on the memory blocks, so that the multiple of memory cells in the plurality of memory cell strings randomly generate different threshold voltage distributions, so as to obtain the PUF data. Therefore, in the embodiment of the disclosure, the memory erasing operation is performed on the memory block so that the plurality of memory cells in the plurality of memory cell strings randomly generate different threshold voltage distributions, and then correspondingly generate PUF data according to the erased memory cell strings. Moreover, the threshold voltage distribution of each memory cells in the erased memory cell string is the same, that is, the corresponding PUF data generated by each page in the memory device is the same. Therefore, when the programming-erasing count of a specific page in the memory device exceeds the wear threshold, another page of the memory device may be used to replace the specific page for increasing the stability of the PUF data.

What is claimed is:

1. A memory erase method for a memory device, comprising:
providing a memory block, wherein the memory block comprises a plurality of memory cell strings including a plurality of memory cells, a plurality of string selection transistors, and a plurality of ground selection transistors, wherein each of the plurality of memory cell strings includes a string selection transistor, multiple memory cells among the plurality of memory cells and a ground selection transistor are connected in series, each memory cell string coupled to a corresponding bit line through a corresponding string selection transistor, and coupled to a common source line through a corresponding ground selection transistor, the multiple of memory cells connected to a plurality of corresponding word lines; and
applying a word line erase voltage to the plurality of corresponding word lines of each of the plurality of memory cell strings;
applying a common source line erase voltage to the common source line;
applying a bit line erase voltage to a corresponding bit line of each of the plurality of memory cell strings;
applying a string selection line erase voltage to the string selection transistor of each of the plurality of memory cell strings, and
applying a ground selection line erase voltage to the ground selection transistor of each of the plurality of memory cell strings,
wherein a voltage difference between the bit line erase voltage and the string selection line erase voltage or a voltage difference between the common source line erase voltage and the ground selection line erase voltage is less than or equal to a predetermined voltage difference, the plurality of memory cells of the plurality of memory cell strings randomly classified as a type-1 erase bit or a type-2 erase bit.

2. The memory erase method for the memory device according to claim 1, further comprising:
correspondingly generating physically unclonable function (PUF) data according to the plurality of memory cells randomly classified into the type-1 erase bit or the type-2 erase bit in the plurality of memory cell strings.

3. The memory erase method for the memory device according to claim 1, wherein a gate induced drain leakage (GIDL) erasing operation is performed on the plurality of memory cells of the plurality of memory cell strings.

4. The memory erase method for the memory device according to claim 3, wherein, after the gate induced drain leakage current erasing operation, all of the multiple memory cells in a specific memory cell string are the type-1 erase bit, or all of the multiple memory cells in a specific memory cell string are the type-2 erase bit.

5. The memory erase method for the memory device according to claim 1, further comprising:
classifying the plurality of memory cells into the type-1 erase bit or the type-2 erase bit according to a threshold voltage of the memory cells.

6. The memory erase method for the memory device according to claim 5, further comprising:
not using unclassifiable memory cells in a condition where the plurality of memory cells cannot be classified as the type-1 erase bit or the type-2 erase bit by using the threshold voltage of the memory cells.

7. The memory erase method for the memory device according to claim 1, wherein the predetermined voltage difference ranges from 0 volts to 5 volts.

8. The memory erase method for the memory device according to claim 1, further comprising:
programming the plurality of memory cells in the memory block before randomly classifying the plurality of memory cells in the plurality of memory cell strings into the type-1 erase bit or the type-2 erase bit.

9. The memory erase method for the memory device according to claim 1, wherein one page in the memory block is constructed by the plurality of memory cells which are connected with one of the corresponding word lines in the plurality of memory cell strings, and,
the memory erase method further comprises:
programming all of the plurality of memory cells in a specific page of the plurality of pages before randomly classifying the plurality of memory cells in the plurality of memory cell strings into the type-1 erase bit or the type-2 erase bit;
determining whether a programming-erasing count of the specific page exceeds a wear threshold; and
using another page of the plurality of pages as the specific page when the programming-erasing count of the specific page exceeds the wear threshold.

10. The memory erase method for the memory device according to claim 1, wherein the word line erase voltage is 0V, the common source line erase voltage is 20V, and the bit line erase voltage is 20V.

11. A memory device, comprising:
a memory block, wherein the memory block comprises a plurality of memory cell strings, the plurality of memory cell strings including a plurality of memory cells, a plurality of string selection transistors and a plurality of ground selection transistors, wherein each of the plurality of memory cell strings includes a string selection transistor, multiple memory cells among the plurality of memory cells and a ground selection transistor are connected in series, each memory cell string coupled to a corresponding bit line through a corresponding string selection transistor, and coupled to a common source line through a corresponding ground selection transistor, the multiple of memory cells connected to a plurality of corresponding word lines;
a memory controller, coupled to the memory block and controlling a plurality of voltage drivers to perform:
applying a word line erase voltage to the plurality of corresponding word lines of each of the plurality of memory cell strings,
applying a common source line erase voltage to the common source line,
applying a bit line erase voltage to a corresponding bit line of each of the plurality of memory cell strings,
applying a string selection line erase voltage to the string selection transistor of each of the plurality of memory cell strings, and
applying a ground selection line erase voltage to the ground selection transistor of each of the plurality of memory cell strings,
wherein a voltage difference between the bit line erase voltage and the string selection line erase voltage or a voltage difference between the common source line erase voltage and the ground selection line erase voltage is less than or equal to a predetermined voltage difference, the plurality of memory cells of the plurality of memory cell strings randomly classified as a type-1 erase bit or a type-2 erase bit.

12. The memory device according to claim 11, wherein the memory controller further performing:
correspondingly generating physically unclonable function data according to the plurality of memory cells randomly classified into the type-1 erase bit or the type-2 erase bit in the plurality of memory cell strings.

13. The memory device according to claim 11, wherein a gate induced drain leakage erasing operation is performed on the plurality of memory cells of the plurality of memory cell strings.

14. The memory device according to claim 13, wherein, after the gate induced drain leakage erasing operation, all of the multiple memory cells in a specific memory cell string are the type-1 erase bit, or all of the multiple memory cells in a specific memory cell string are the type-2 erase bit.

15. The memory device according to claim 11, wherein the memory controller further performing:
classifying the plurality of memory cells into the type-1 erase bit or the type-2 erase bit according to a threshold voltage of the memory cells.

16. The memory device according to claim 15, wherein the memory controller further performing:
not using unclassifiable memory cells in a condition where the plurality of memory cells cannot be classified as the type-1 erase bit or the type-2 erase bit by using the threshold voltage of the memory cells.

17. The memory device according to claim 11, wherein the predetermined voltage difference ranges from 0 volts to 5 volts.

18. The memory device according to claim 11, wherein the memory controller further performing:
programming the plurality of memory cells in the memory block before randomly classifying the plurality of memory cells in the plurality of memory cell strings into the type-1 erase bit or the type-2 erase bit.

19. The memory device according to claim 11, wherein one page in the memory block is constructed by the plurality of memory cells which are connected with one of the corresponding word lines in the plurality of memory cell strings, and,
wherein the memory controller further performing:
programming all of the plurality of memory cells in a specific page of the plurality of pages before randomly classifying the plurality of memory cells in the plurality of memory cell strings into the type-1 erase bit or the type-2 erase bit;
determining whether a programming-erasing count of the specific page exceeds a wear threshold; and
using another page of the plurality of pages as the specific page when the programming-erasing count of the specific page exceeds the wear threshold.

20. The memory device according to claim 11, wherein the word line erase voltage is 0V, the common source line erase voltage is 20V, and the bit line erase voltage is 20V.
